(19) United States
(12) Patent Application Publication
(10) Pub. No.: US 2013/0048801 A1
(43) Pub. Date: Feb. 28, 2013

(54) Low-Profile Stand

(71) Applicant: Brian Weinberg, San Diego, CA (US)

(72) Inventor: Brian Weinberg, San Diego, CA (US)

(73) Assignee: ENCLAVE TECHNOLOGIES, San Diego, CA (US)

(21) Appl. No.: 13/219,742

(22) Filed: Aug. 29, 2011

(51) Int. Cl. H05K 7/00

(52) U.S. Cl. 248/121

(57) ABSTRACT

The present invention generally relates to a low profile stand for use with mobile computing devices. Specifically, this invention relates to a low-profile stand configured to be placed on a surface and retain a mobile computing device at one or more desirable angles to allow for convenient use by a user.

### FIELD OF THE INVENTION

The present invention generally relates to a low profile stand for use with mobile computing devices. Specifically, this invention relates to a low-profile stand configured to be placed on a surface and retain a mobile computing device at one or more desirable angles to allow for convenient use by a user.

### BACKGROUND OF THE INVENTION

As portable devices become more powerful, portable and functional, their use become more and more ubiquitous. Frequently, devices are used on the go, with users holding a device in one hand and operating the device with the other. This practice can be limiting, especially in situations where one or more of the user's hands are otherwise occupied (e.g., when operating a motor vehicle, taking notes).

Even where both of a user's hands are free, the requirement that one hand be used to hold a portable device while the other hand interacts with the portable device can lead to inaccuracies in interaction or, at the very least, diminished speed. Take for example, typing. Typing on a portable device with one hand is unquestionably slower than typing with both hands.

Additionally, there is a certain level of user fatigue that is created by requiring the holding of a portable device during operation. Even in the scenario where the portable device may be laid on a surface and viewed/used, this still creates an uncomfortable or at least an inconvenient angle for viewing, commonly requiring a user to lurch forward and hunch over the portable device.

Therefore, there is a need in the art for a low-profile stand that can allow a user to view and operate a portable device without requiring the user to actively hold the portable device, said low-profile stand further configured to be maintain the portable device in one or more optimal viewing angles. These and other features and advantages of the present invention will be explained and will become obvious to one skilled in the art through the summary of the invention that follows.

### SUMMARY OF THE INVENTION

The present invention provides a low-profile stand for maintaining a portable device on a surface in one or more optimal viewing angles. According to an embodiment of the present invention, the low-profile stand is comprised of a hinged replaceable device adapter rod and a base.

According to an embodiment of the present invention, a base of the low-profile stand is comprised of one or more support legs and a device adapter rod retention component. The one or more support legs are configured to allow for the low-profile stand to be retained on a surface. The device adapter rod retention component is comprised of one or more channels for receiving one or more ends of a device adapter rod and one or more locking tab channels for receiving one or more locking tabs.

According to an embodiment of the present invention, the base may be further comprised of one or more optional hard stops configured to prevent a device from being placed in a non-desirable angle or/and to increase rigidity of the assembly (device, base, and adapter) when touch typing.

According to an embodiment of the present invention, a device adapter rod is configured to be received in said one or more channels of said device adapter rod retention component on said base. The device adapter rod is further configured to allow a device retained within a device channel formed from one or more walls of said device adapter rod and allow the device to be positioned at one or more desirable angles.

According to an embodiment of the present invention, a device adapter rod may be further comprised of a pressure angle locking mechanism configured to extend one or more locking tabs into complimentary one or more locking tab channels located on said base.

The foregoing summary of the present invention with the preferred embodiments should not be construed to limit the scope of the invention. It should be understood and obvious to one skilled in the art that the embodiments of the invention thus described may be further modified without departing from the spirit and scope of the invention.

### BRIEF DESCRIPTION OF THE DRAWINGS

FIG. 1 is a front perspective view of a low-profile stand in accordance with an embodiment of the present invention;

FIG. 2 is a front perspective view of a low-profile stand in accordance with an embodiment of the present invention;

FIG. 3 is a rear perspective view of a low-profile stand in accordance with an embodiment of the present invention;

FIG. 4 is a side perspective view of a low-profile stand, with a device resting against a hard stop, in accordance with an embodiment of the present invention;

FIG. 5 is a side perspective view of a low-profile stand, with a device in an exemplary desirable angle, in accordance with an embodiment of the present invention;

FIG. 6 is a side perspective view of a low-profile stand, with a device in an exemplary desirable angle, in accordance with an embodiment of the present invention;

FIG. 7 is a side perspective view of a low-profile stand, with a device in an exemplary desirable angle, in accordance with an embodiment of the present invention;

FIG. 8 is a side perspective view of a low-profile stand, with a device in an exemplary desirable angle, in accordance with an embodiment of the present invention;

FIG. 9 is a side perspective view of a low-profile stand, with a device in an exemplary desirable angle, in accordance with an embodiment of the present invention;

FIG. 10 is a cross-sectional detail view of a low-profile stand with a bottom integrated angle lock, in accordance with an embodiment of the present invention;

FIG. 11 is a cross-sectional detail view of a low-profile stand with a bottom integrated angle lock, in accordance with an embodiment of the present invention;

FIG. 12 is a cross-sectional detail view of a low-profile stand with a bottom integrated angle lock, in accordance with an embodiment of the present invention;

FIG. 13 is a bottom view of a low-profile stand, in accordance with an embodiment of the present invention;

FIG. 14 is a side view of a low-profile stand, in accordance with an embodiment of the present invention;

FIG. 15 is a top view of a low-profile stand, in accordance with an embodiment of the present invention;

FIG. 16 is a back view of a device adapter rod, in accordance with an embodiment of the present invention;

FIG. 17 is a front view of a device adapter rod, in accordance with an embodiment of the present invention;

FIG. 18 is a side view of a device adapter rod, in accordance with an embodiment of the present invention;

FIG. 19 is a front perspective view of a low-profile stand in accordance with an embodiment of the present invention;

FIG. 20 is a side view of a low-profile stand, with a device in an exemplary desirable angle, in accordance with an embodiment of the present invention;

FIG. 21 is a side view of a low-profile stand, with a device in an exemplary desirable angle, in accordance with an embodiment of the present invention;

FIG. 22 is a side view of a low-profile stand, with a device in an exemplary desirable angle, in accordance with an embodiment of the present invention;

FIG. 23 is a front perspective view of a base, in accordance with an embodiment of the present invention;

FIG. 24 is a front perspective view of a device adapter rod, in accordance with an embodiment of the present invention;

FIG. 25 is a side view of a device adapter rod, in accordance with an embodiment of the present invention;

FIG. 26 is a front perspective view of a low-profile stand, in accordance with an embodiment of the present invention;

FIG. 27 is a cross-sectional detail view of a low-profile stand, in accordance with an embodiment of the present invention;

FIG. 28 is a front perspective view of a low-profile stand, in accordance with an embodiment of the present invention;

FIG. 29 is a cross-sectional detail view of a low-profile stand, in accordance with an embodiment of the present invention;

FIG. 30 is a side view of a low-profile stand, with a device in an exemplary desirable angle, in accordance with an embodiment of the present invention;

FIG. 31 is a side view of a low-profile stand, with a device in an exemplary desirable angle, in accordance with an embodiment of the present invention;

FIG. 32 is a front perspective view of a low-profile stand scaled to fit tablet computer devices, in accordance with an embodiment of the present invention;

FIG. 33 is a front perspective view of a low-profile stand scaled to fit tablet computer devices, in accordance with an embodiment of the present invention;

FIG. 34 is a front view of a low-profile stand scaled to fit tablet computer devices, in accordance with an embodiment of the present invention;

FIG. 35 is a top view of a low-profile stand, in accordance with an embodiment of the present invention; and

FIG. 36 is a top view of a low-profile stand, in accordance with an embodiment of the present invention.

### DETAILED SPECIFICATION

The present invention generally relates to a low profile stand for use with mobile computing devices. Specifically, this invention relates to a low-profile stand configured to be placed on a surface and retain a mobile computing device at one or more desirable angles to allow for convenient use by a user.

According to an embodiment of the present invention, the low-profile stand is comprised of a hinged replaceable device adapter rod and a base.

According to an embodiment of the present invention, a base of the low-profile stand is comprised of one or more support legs and a device adapter rod retention component. The one or more support legs are configured to allow for the low-profile stand to be retained on a surface. The device adapter rod retention component is comprised of one or more channels for receiving one or more ends of a device adapter rod and one or more locking tab channels for receiving one or more locking tabs.

The one or more support legs are designed to give the low-profile stand a low center of gravity and provide for a stable base, even when a computing device is extending from a device adapter rod. A lower portion of each support leg may be configured to receive one or more traction components, such as suction cups or felt pads. In this manner, the fraction components help to provide the low-profile tool with traction in order to prevent the low-profile stand from slipping or moving unintentionally.

According to an embodiment of the present invention, a base may be further comprised of one or more optional hard stops configured to prevent a device from being placed in a non-desirable angle. In an exemplary embodiment of the present invention, the one or more hard stops are located on a top portion of one or more support legs of the base. Ideally, the hard stops are located in such a manner as to make contact with a rigid portion of the computing device retained by a device adapter rod. In this manner, the hard stops do not put pressure on, or come in contact with, potentially sensitive components of the computing device (e.g., a touch screen).

According to an embodiment of the present invention, a device adapter rod is configured to be received in said one or more channels of said device adapter rod retention component on said base. The device adapter rod is further configured to allow a computing device retained within a device channel formed from one or more walls of said device adapter rod and allow the device to be positioned at one or more desirable angles. Computing devices that may be retained include, but are not limited to, tablet PCs, handheld game systems, mobile phones, smartphones, calculators and portable media players. One of ordinary skill in the art would appreciate that there are numerous types of computing devices that could be retained by a device adapter rod in accordance with embodiments of the present invention, and embodiments of the present invention are contemplated for use with any type of computing device. Furthermore, embodiments of the present invention can be configured to retain a computing device in a landscape position, a portrait position or any combination thereof.

According to an embodiment of the present invention, a device adapter rod may be further comprised of a pressure angle locking mechanism configured to extend one or more locking tabs into complimentary one or more locking tab channels located on said base. Once the locking tabs have been received in the complimentary locking tab channels, the device adapter rod and any retained computing device are locked into place. In an exemplary embodiment, by being locked into place, the computing device and device adapter rod are set at a fixed angle, representing the angle at which the device adapter rod was at when locked into place.

In an alternate embodiment, by being locked into place, the computing device and device adapter rod able to be rotated back and forth across numerous viewing angles, where such rotation requires an application of a moderate level of torque. The torque required to move change the viewing angle may vary, depending on the number of locking tabs and complimentary channels and the type of computing device to be retained within said device adapter rod. Generally, the larger the computing device to be retained, the greater amount of torque is desired. Additionally, torque requirements may also be variable based on application. For instance, the amount of torque to change angles for a low-profile stand that is to be used in a moving vehicle may be higher than a low-profile stand that is to be used in a stationary environment (e.g., on a desk).

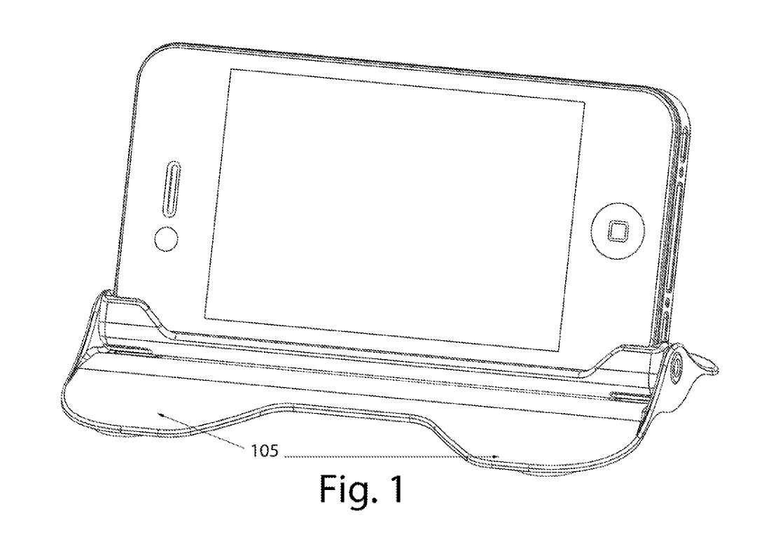

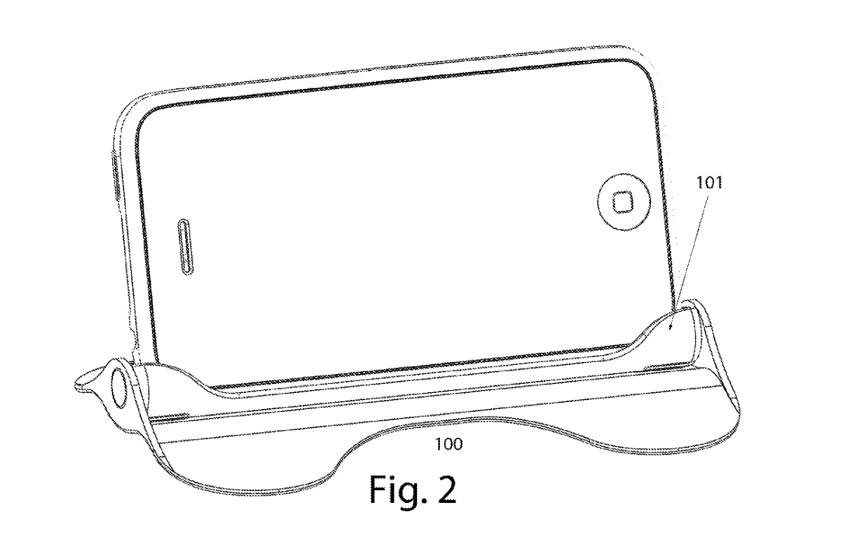

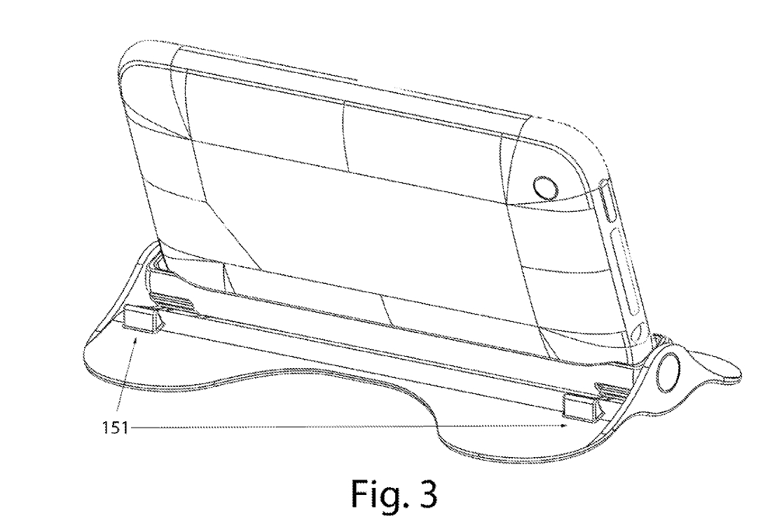

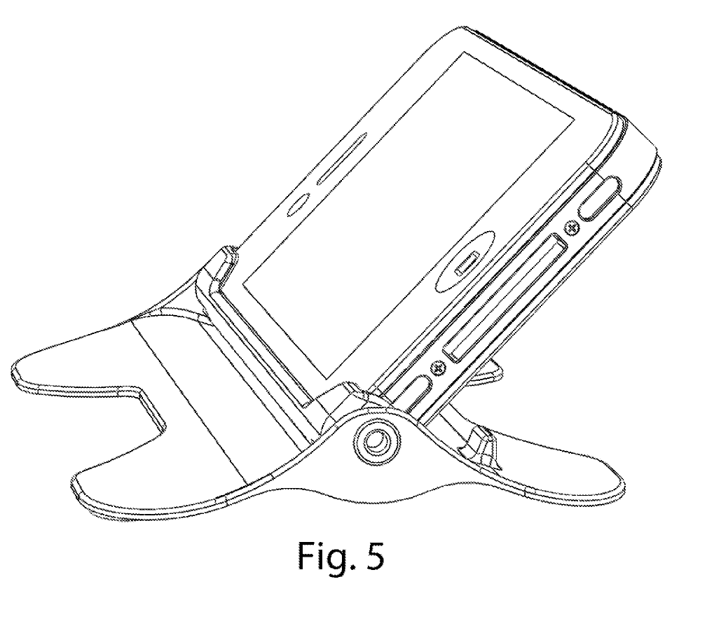

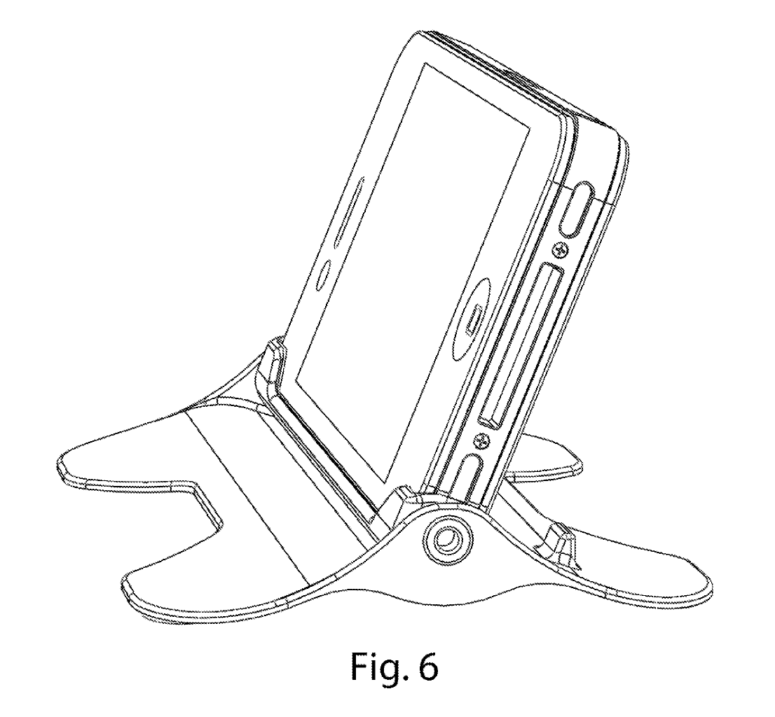

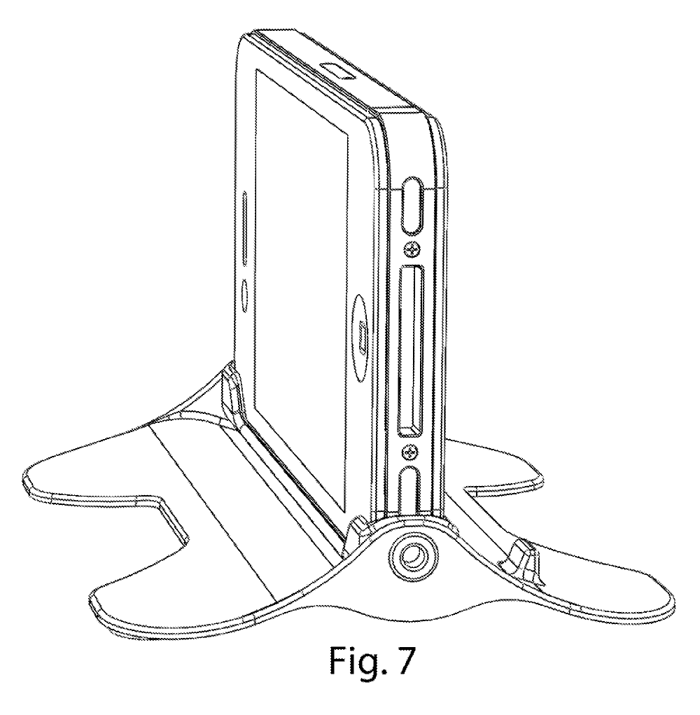

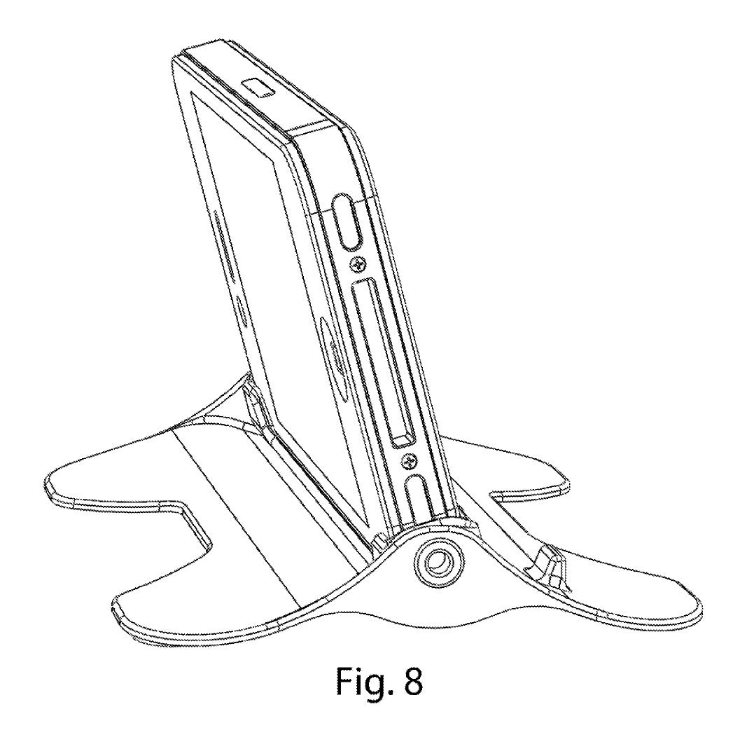

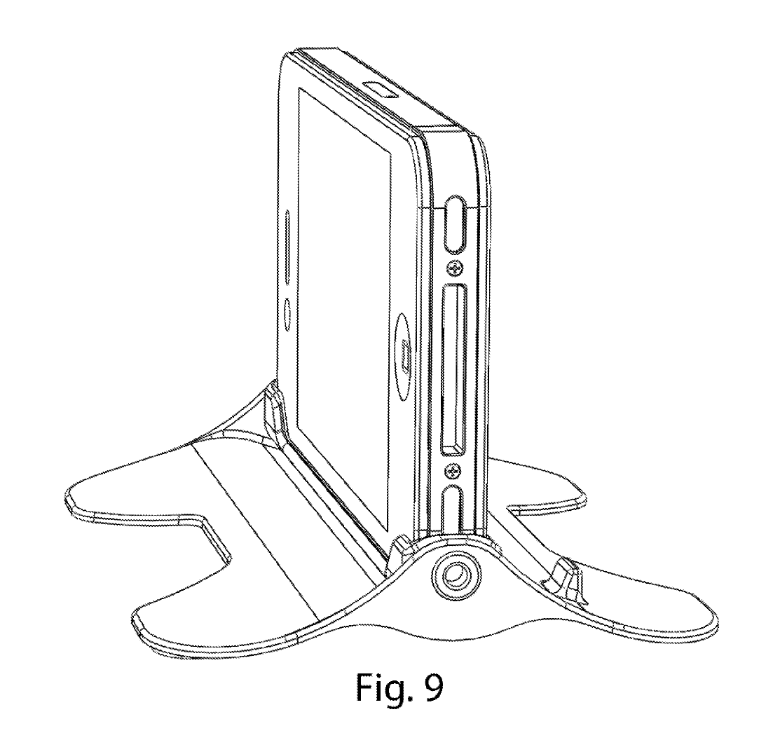

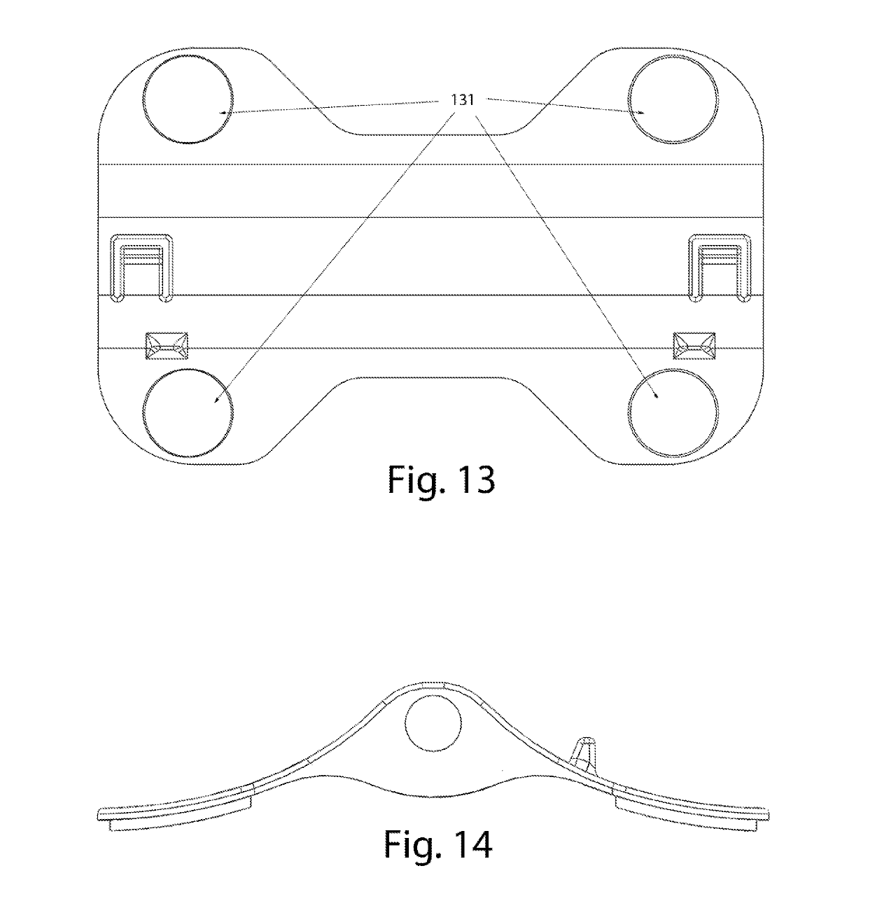

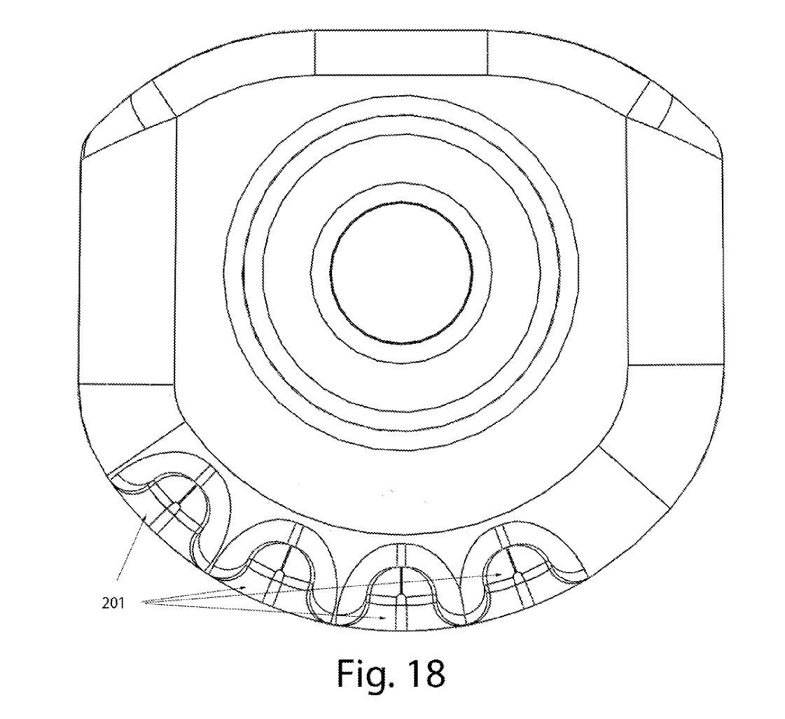

Turning now to FIGS. 1-18, an exemplary embodiment of a low-profile stand is shown. In these figures, a base 100 with four support legs 105 is shown. Each of the four support legs is further comprised of a traction component located on a lower portion of the support leg. A clear representation of this can be seen in FIG. 13, where a non-slip pad 131 is attached to each of the four support legs shown.

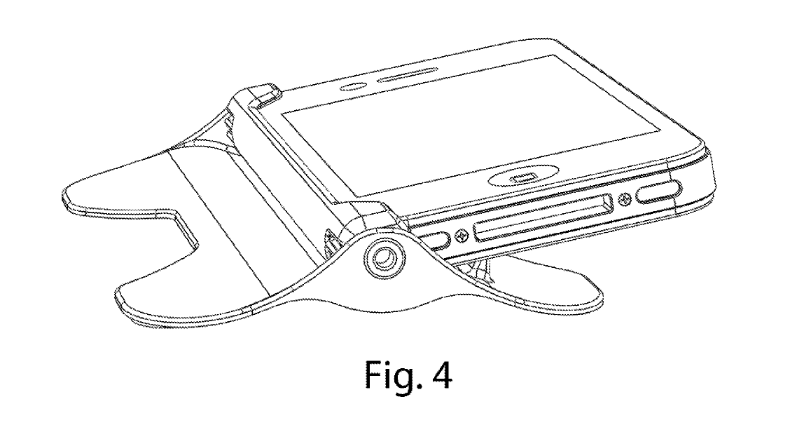

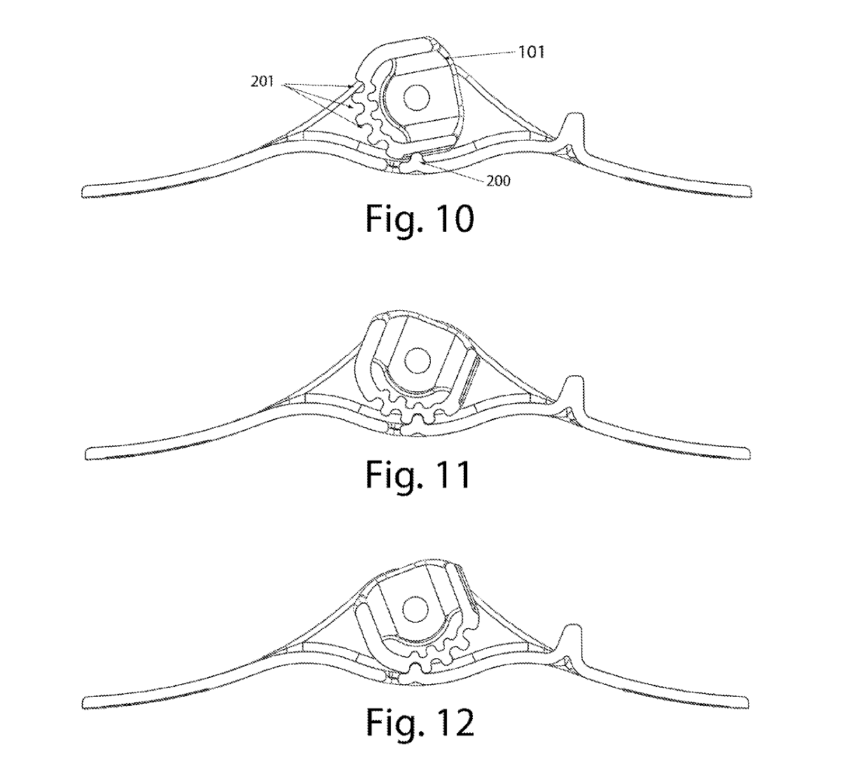

FIGS. 10-12 show a cross-sectional detail view of a low-profile stand comprised of a base with a locking tabs 200 and a device adapter rod 101 with multiple locking channels 201. Each locking channel provides the ability for the computing device retained within the device adapter rod to be locked into a different desirable angle, as shown in FIGS. 4-9.

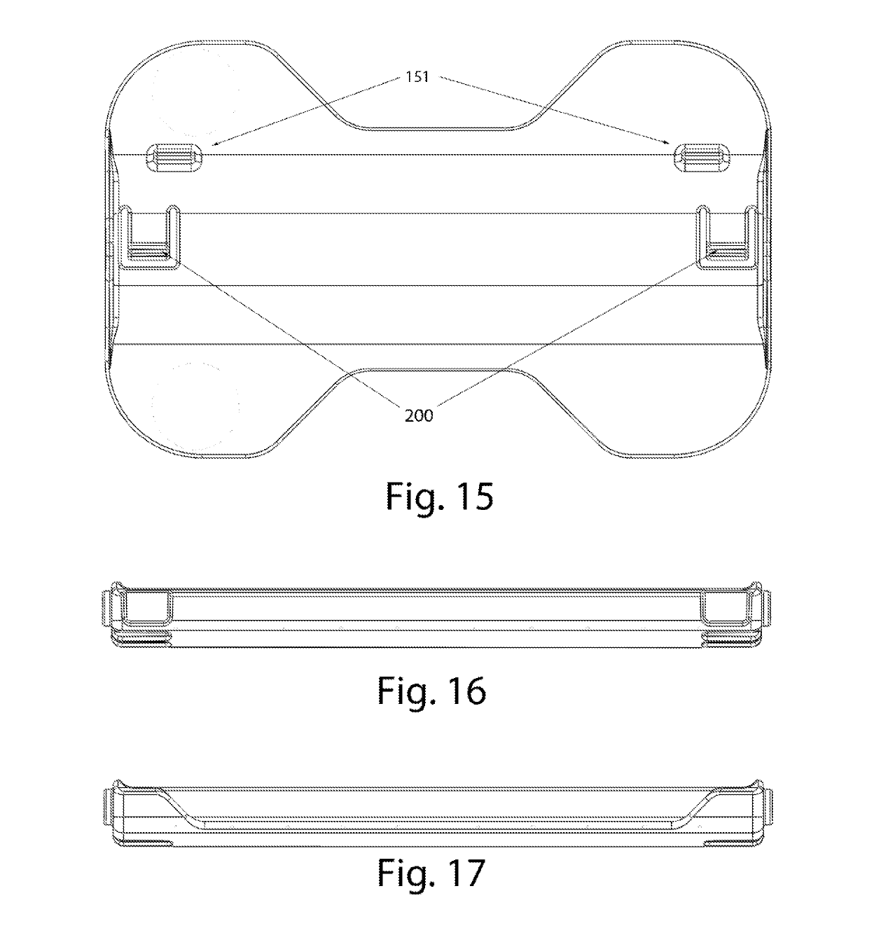

FIG. 15 shows a clear view of two hard stops 151 in exemplary locations on a low-profile stand.0

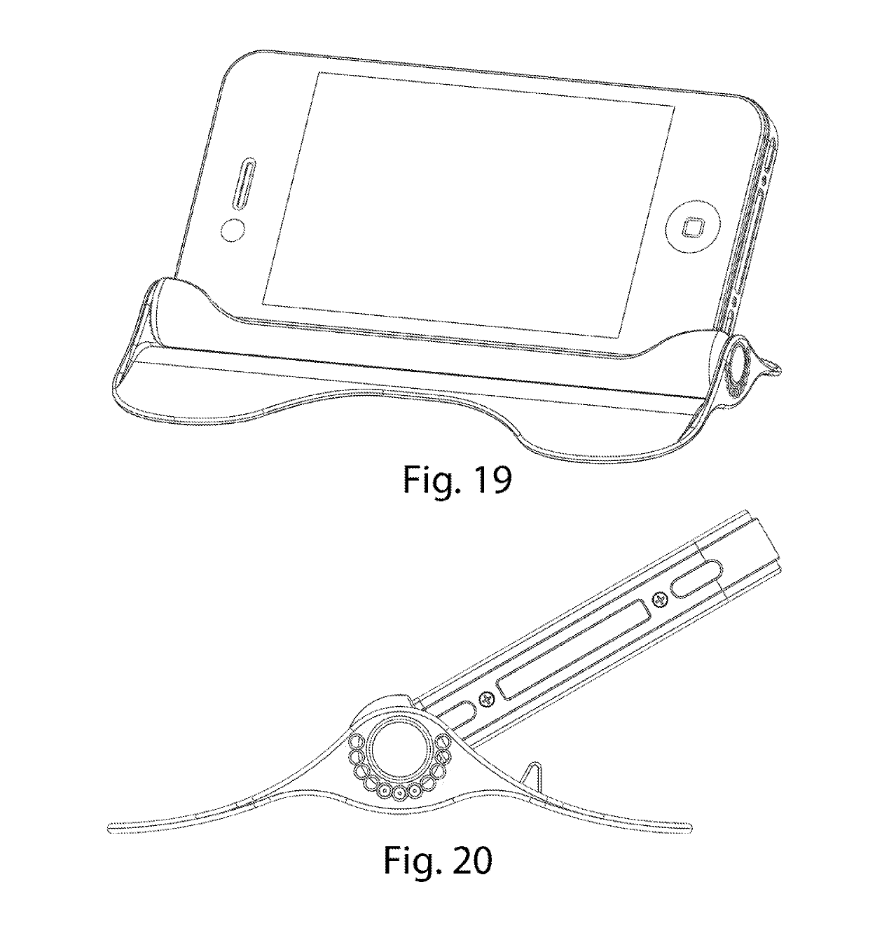

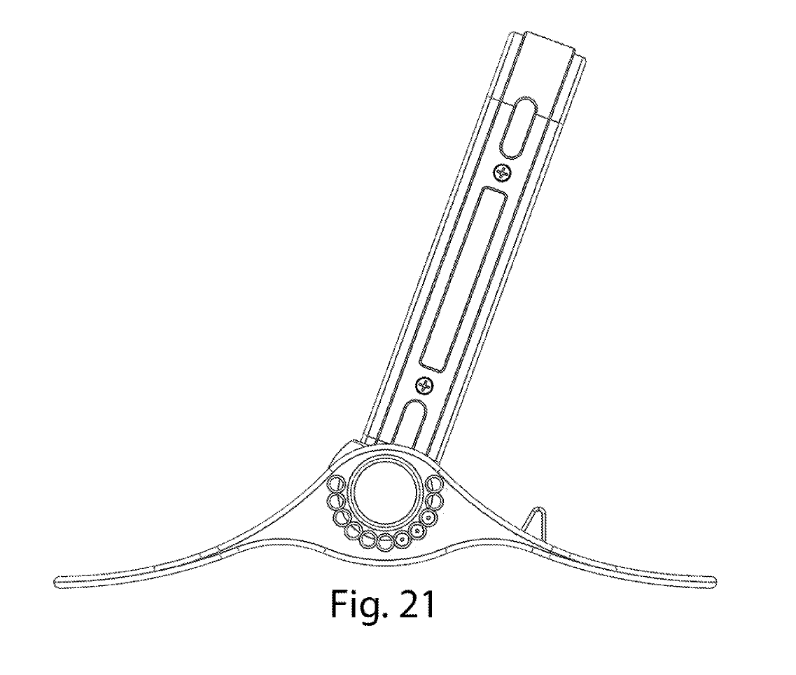

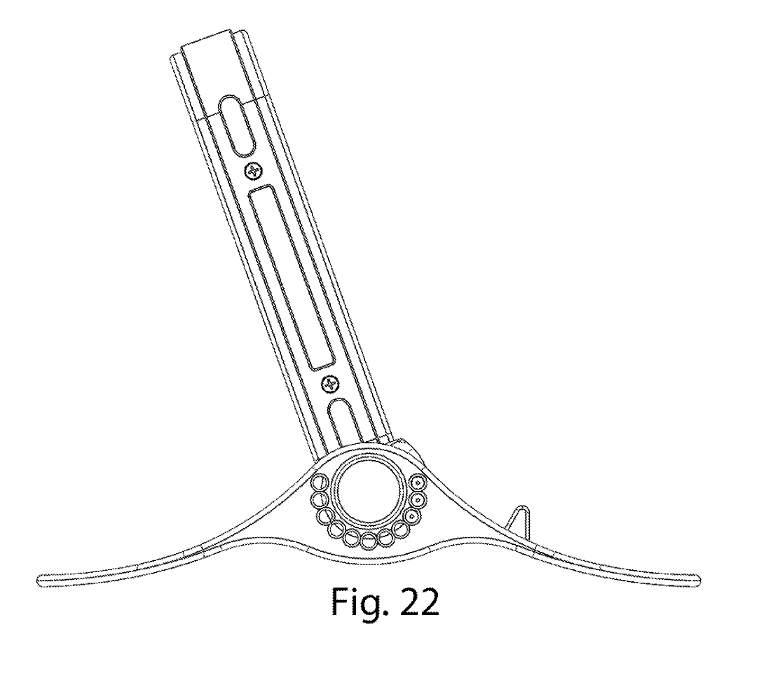

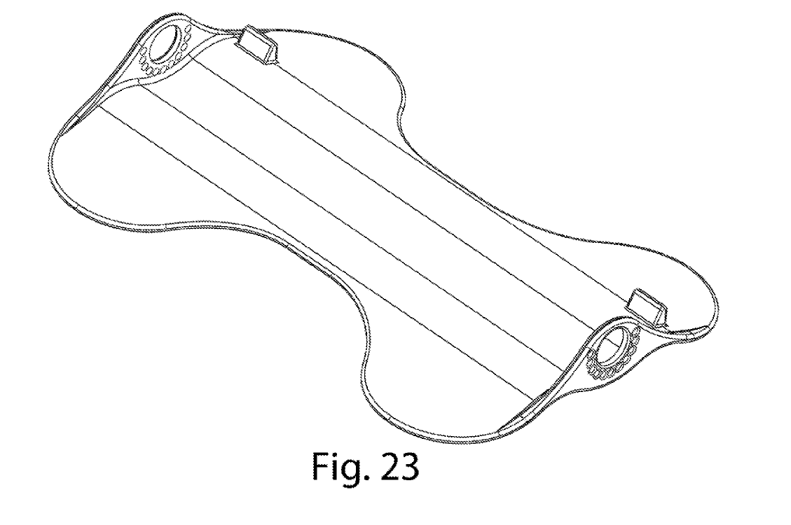

FIGS. 19-25 show another exemplary embodiment of the low-profile stand in accordance with an embodiment of the present invention. In this embodiment, the locking tabs and channels are located on the sides of the low-profile stand and device adapter rod.

In this embodiment, the locking tabs of the device adapter rod are received within locking channels located on the side portion of the base near the device adapter rod retention component. FIGS. 19-22 show the low-profile stand, in accordance with the exemplary embodiment herein described, in different desirable angles.

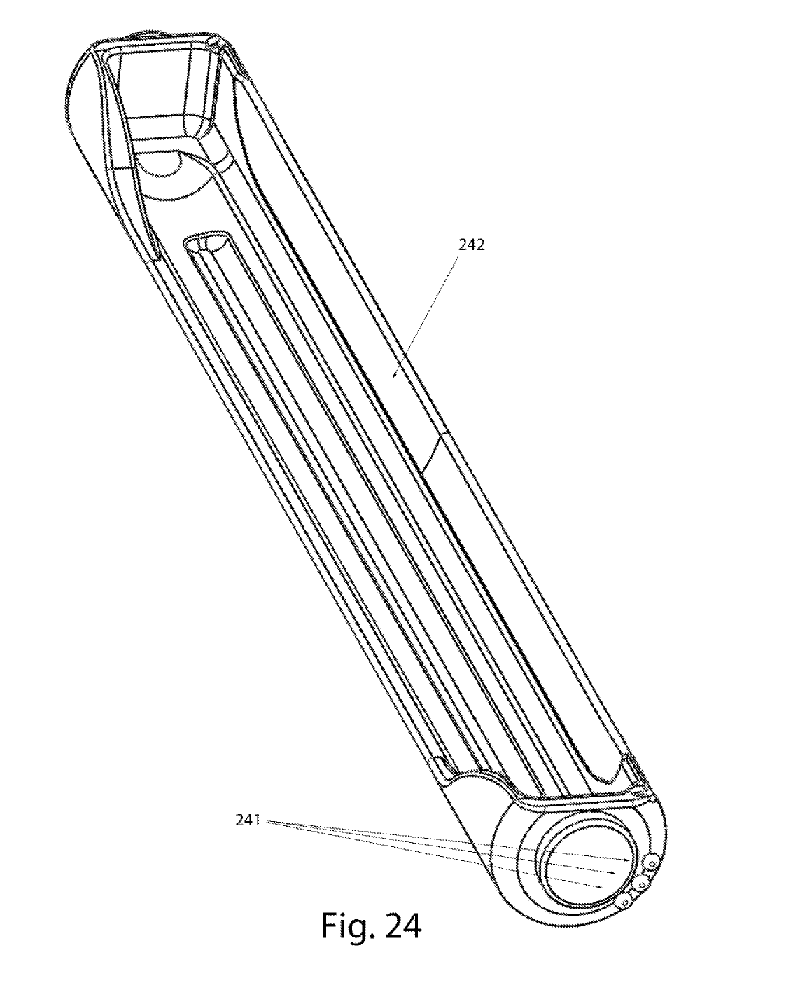

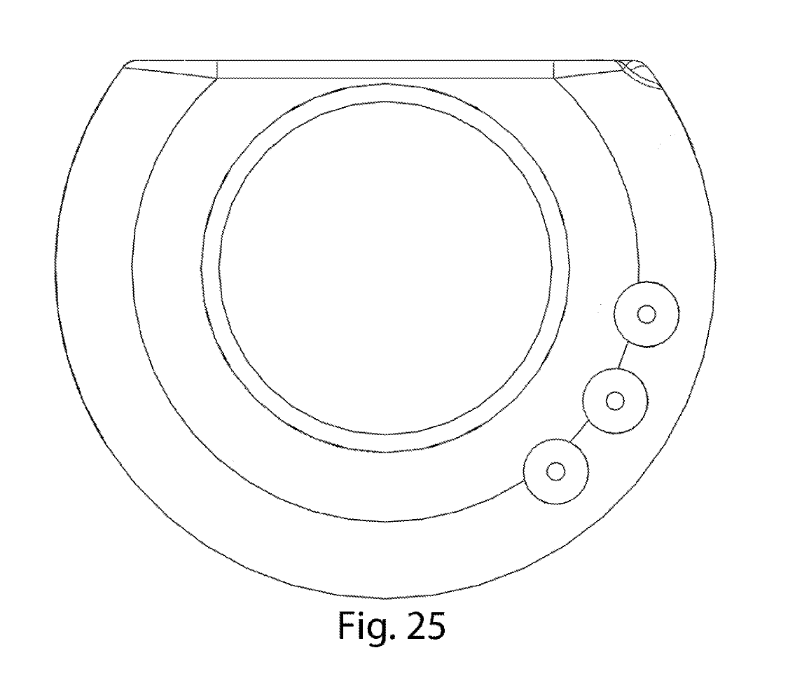

As shown in FIG. 24, a device adapter rod can be comprised of one or more locking tabs. In an exemplary configuration, the more locking tabs utilized, the greater the amount of torque is required to move the device adapter rod to alternate desirable angles. FIG. 24 shows 3 locking tabs 241. Ideally, the number of locking tabs on each side of the device adapter rod will be equal.

Also shown in FIG. 24 are walls configured to retain a computing device in said device adapter rod. The walls are configured to fit one or more types of computing devices. In an exemplary embodiment, cutout features 242 may be utilized to allow for multiple types of computing devices to be retained by a single device adapter rod.

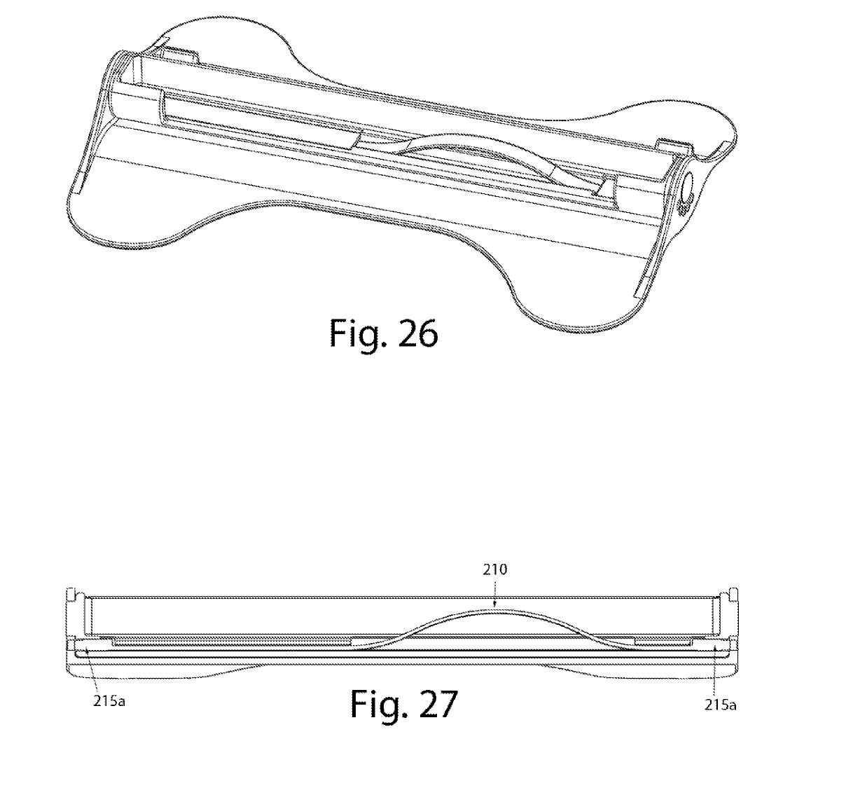

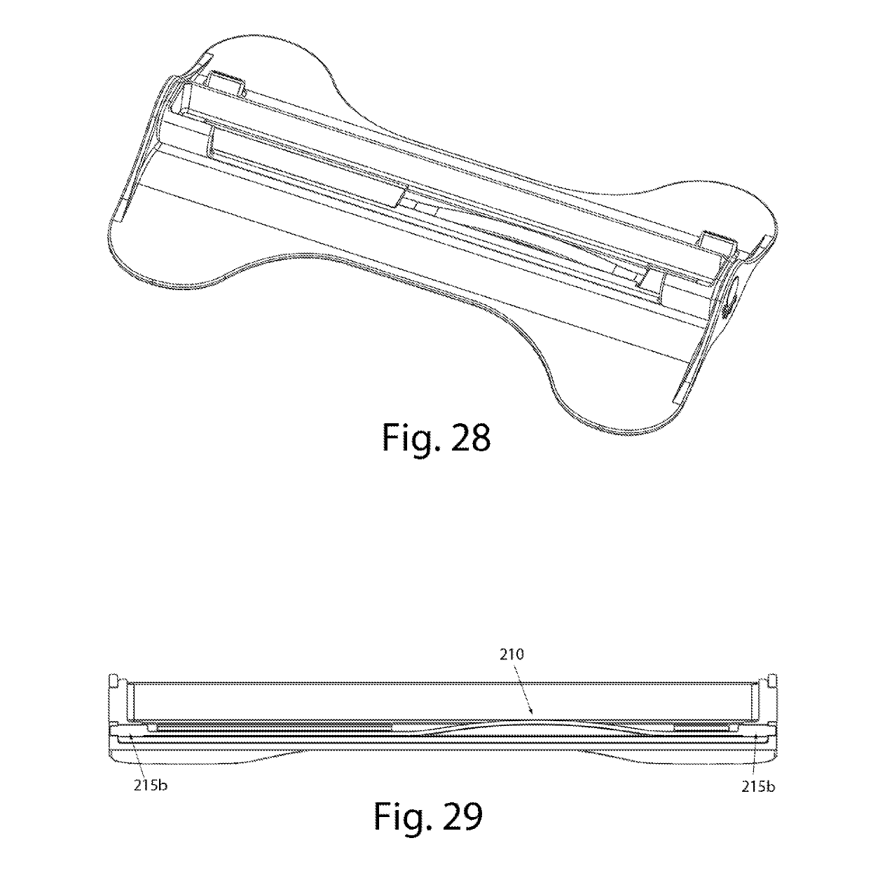

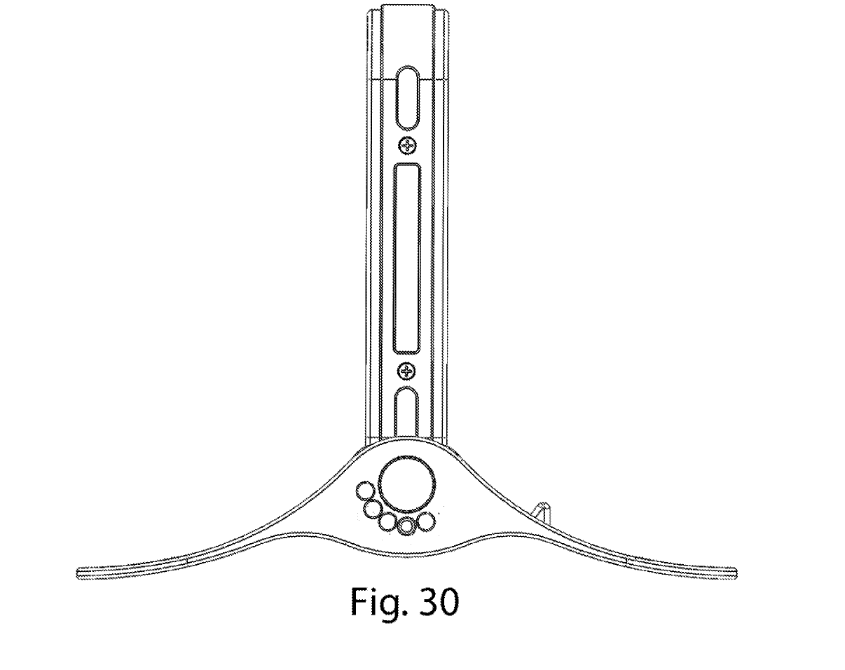

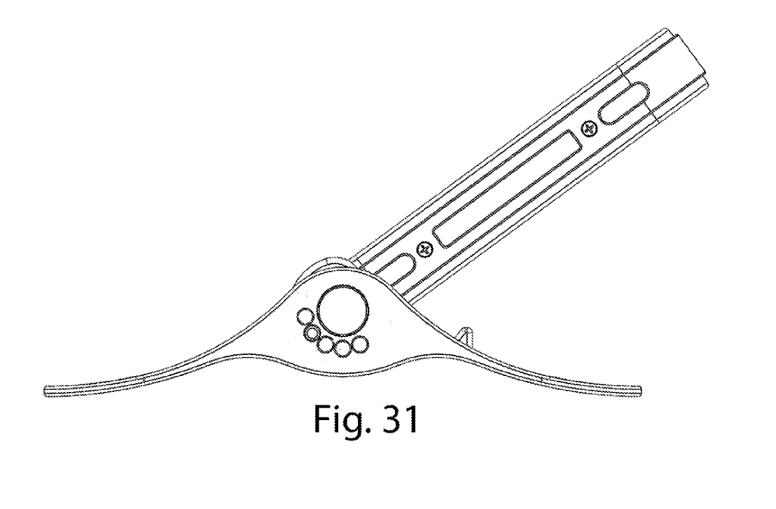

FIGS. 26-31 shows an exemplary embodiment of a locking mechanism, in accordance with embodiments of the present invention. In these figures, a locking mechanism 210 is shown, whereby as a computing device is placed into the device adapter rod, the locking mechanism 210 is forced downward, pushing one or more locking tabs 215 outward into one or more complimentary locking channels located on a base. In an exemplary embodiment, the locking mechanism its molded in an unlocked position, such that, when a computing device is placed into the device adapter rod, outward force is generated upon the locking tabs 215b, and when the computing device is removed, the locking mechanism returns to its unlocked position, retracting the locking tabs 215a.

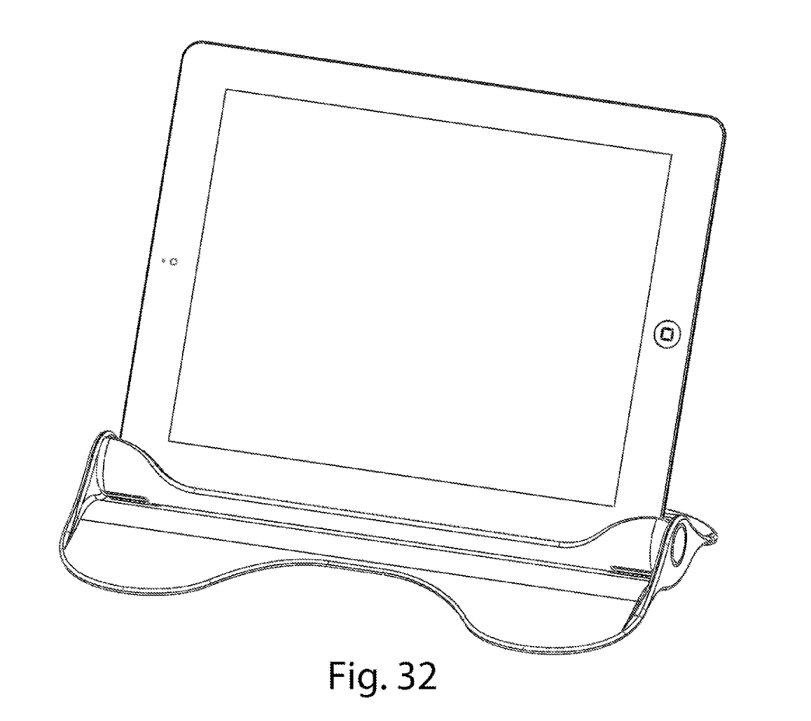

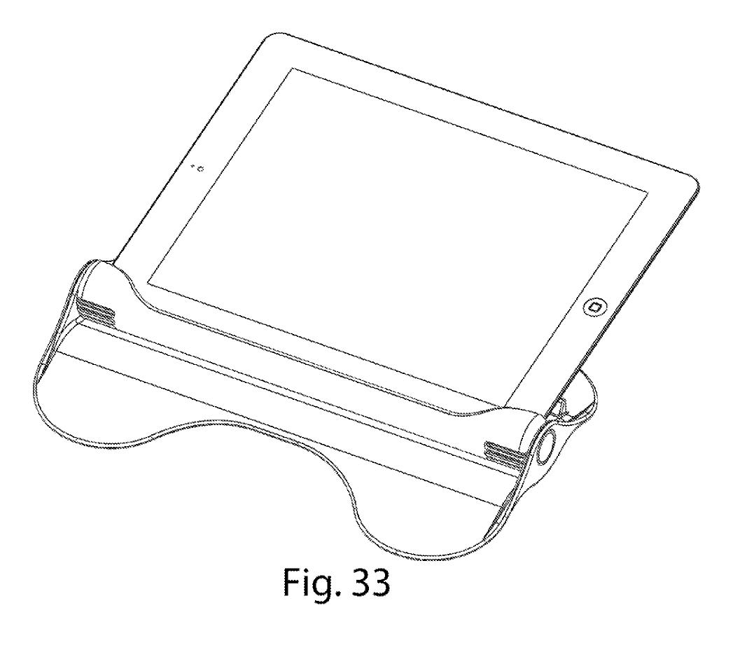

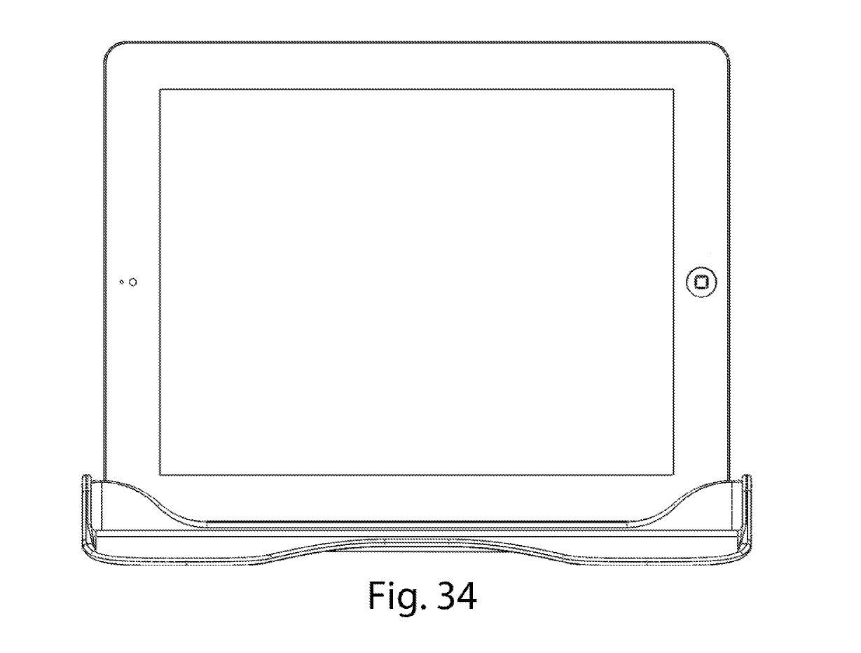

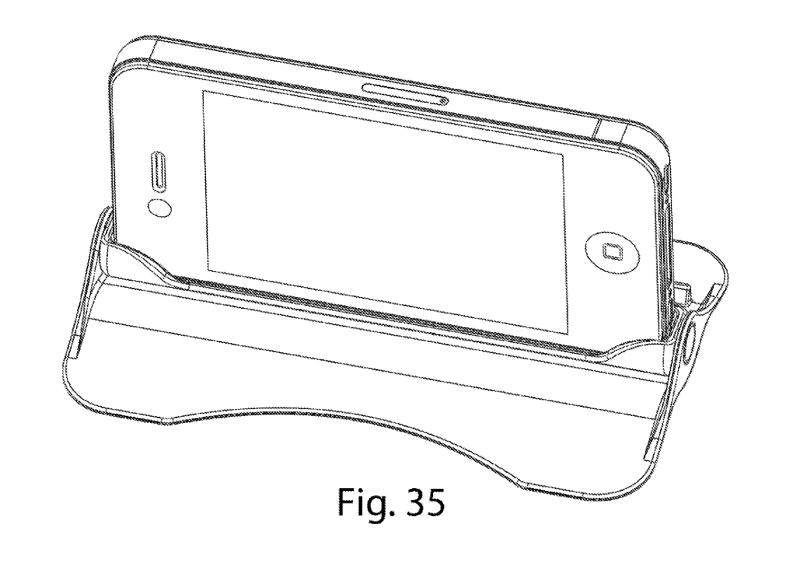

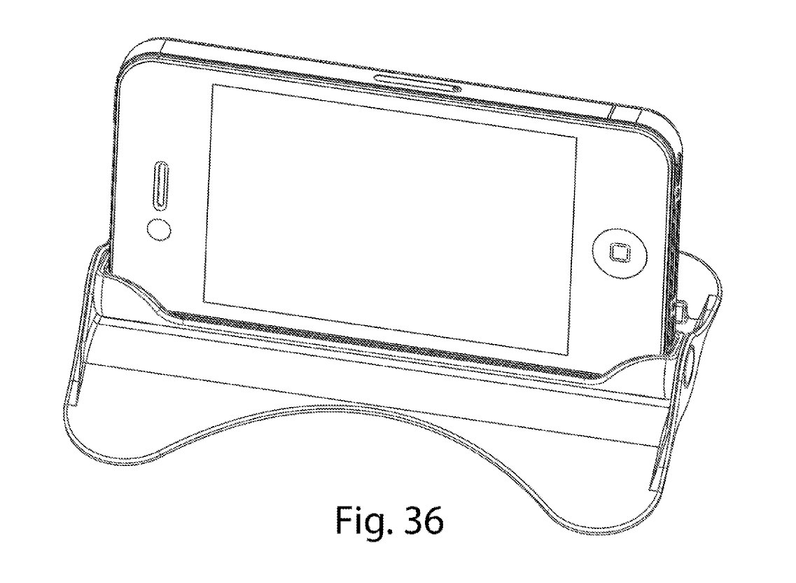

Turning now to FIGS. 32-34, an exemplary embodiment of the present invention is shown in which the low-profile stand is configured to receive larger computing devices, such as a tablet PC. Other than being scaled up for size, the functionality and components remain the same. Additional reinforcing, stronger materials and additional locking tabs and channels may be utilized in order to improve the functional aspects of the invention.

It should be noted that the features illustrated in the drawings are not necessarily drawn to scale, and features of one embodiment may be employed with other embodiments as the skilled artisan would recognize, even if not explicitly stated herein. Descriptions of well-known components and processing techniques may be omitted so as to not unnecessarily obscure the embodiments.

While multiple embodiments are disclosed, still other embodiments of the present invention will become apparent to those skilled in the art from this detailed description. The invention is capable of myriad modifications in various obvious aspects, all without departing from the spirit and scope of the present invention. Accordingly, the drawings and descriptions are to be regarded as illustrative in nature and not restrictive.

1. A low-profile stand, said low-profile stand comprising:
a base comprised of one or more support legs and a device rod retention component,
wherein said device rod retention component is comprised of one or more device adapter rod receiving channels and one or more locking channels; and
a device adapter rod comprised of one or more walls configured to receive and retain a computing device, one or more ends configured to be received within said one or more device adapter rod receiving channels and one or more locking tabs configured to be received within one or more of said one or more locking channels.

2. The low-profile stand of claim 1, wherein said base if further comprised of one or more hard stops.

3. The low-profile stand of claim 1, wherein each one of said one or more support legs is comprised of a traction component attached to a lower portion of said support leg.

4. The low-profile stand of claim 1, wherein said computing device is a smart phone.

5. The low-profile stand of claim 1, wherein said computing device is a tablet PC.

6. The low-profile stand of claim 1, wherein said computing device is retained in a landscape orientation.

7. The low-profile stand of claim 1, wherein said computing device is retained in a portrait orientation.

8. The low-profile stand of claim 1, wherein said one or more locking channels are located on a side of said base.

9. The low-profile stand of claim 1, wherein said one or more locking channels are located on an upper portion of said base.

10. The low profile stand of claim 1, wherein said one or more adapter rod receiving channels are located on one or more sides of said base.
